(19) United States
(12) Patent Application Publication
(10) Pub. No.: US 2025/0139337 A1
(43) Pub. Date: May 1, 2025

(54) PERSISTENT PROMPTS FOR GENERATIVE ARTIFICIAL INTELLIGENCE SYSTEMS

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/918,955

(22) Filed: Oct. 17, 2024

Related U.S. Application Data
(60) Provisional application No. 63/593,498, filed on Oct. 26, 2023.

(51) Int. Cl. G06F 30/27; G06F 30/12

(52) U.S. Cl. CPC G06F 30/27; G06F 30/12

(57) ABSTRACT

A computer-implemented method for generating design objects for computer-aided drawing (CAD) design, comprises combining at least two of a first input received from a first client device and one or more persistent intents to generate a composite prompt, inputting the composite prompt into a trained machine learning (ML) model for execution, receiving a design object generated by the trained ML model in response to the composite prompt; and displaying the design object in a design space that includes the CAD design.

### CROSS-REFERENCE TO RELATED APPLICATIONS

This application claims priority benefit of the United States Provisional Patent Application titled “IMPLEMENTING MULTIPLE USER INTERFACES FOR PROMPTS IN CONNECTION WITH AN ARTIFICIAL INTELLIGENCE MODEL,” filed on Oct. 26, 2023, and having Ser. No. 63/593,498. The subject matter of this related application is hereby incorporated herein by reference.

### BACKGROUND

### Field of the Various Embodiments

The various embodiments relate generally to computer-aided design and artificial intelligence and, more specifically, to persistent prompts for generative artificial intelligence systems.

### Description of the Related Art

Design exploration for three-dimensional (3D) objects generally refers to a phase of a design process during which a designer generates and evaluates various designs alternatives for one or more 3D objects within a larger 3D design project. As is well-understood in practice, manually generating multiple designs for even a relatively simple 3D object can be very labor-intensive and time-consuming. Because the time allocated for generating a design for a specific 3D object is usually limited, a designer typically produces only a small number of non-optimized 3D design objects for any given larger 3D design project, which can negatively impact the overall quality of the larger 3D design project. Accordingly, various conventional computer-aided design (CAD) applications have been developed that attempt to automate more fully how 3D objects are generated and evaluated.

In this regard, some conventional CAD applications implement an artificial intelligence (AI) model, such as a generative machine learning (ML) model, to automatically synthesize 3D objects in response to prompts entered by an operator of the CAD application. In operation, the AI model responds to one or more operator prompts by executing various optimization algorithms to generate 3D design objects that satisfy one or more design characteristics specified in the operator prompt(s). In some cases, the AI model generates a single 3D design object that the operator can then incorporate into a larger 3D design project. In other cases, the AI model generates numerous alternative 3D design objects and presents those alternative designs to the operator for evaluation and selection.

One drawback of using AI models to further automate the design process is that the operator prompts generated by conventional CAD applications oftentimes fail to include or reflect the full range of information a designer wants to convey to a given AI model about his/her design. In particular, conventional CAD applications are not able to generate operator prompts that include or reflect the design goals and constraints for larger 3D design projects. Instead, conventional CAD applications can only generate operator prompts that include or reflect the design goals and constraints for the individual 3D design objects that the operator manually incorporates into larger 3D design projects. Consequently, when an AI model receives operator prompts generated by a conventional CAD application, the AI model is usually unable to generate 3D design objects that accurately reflect any of the design intents or design ideas associated with the larger 3D design project, which oftentimes reduces the overall quality of the larger 3D design project.

As the foregoing illustrates, what is needed in the art are more effective techniques for automatically generating designs using artificial intelligence models.

### SUMMARY

In various embodiments, a computer-implemented method for generating design objects for computer-aided drawing (CAD) design, comprises combining at least two of a first input received from a first client device and one or more persistent intents to generate a composite prompt, inputting the composite prompt into a trained machine learning (ML) model for execution, receiving a design object generated by the trained ML model in response to the composite prompt; and displaying the design object in a design space that includes the CAD design.

At least one technical advantage of the disclosed techniques relative to the prior art is that the disclosed techniques can be used to enable a CAD application to combine inputs entered by an operator with one or more intents associated with a larger 3D design project. Inclusion of the such intents in the prompts that are transmitted to an AI system allows the AI system to understand the intents for the larger 3D design project more accurately. The AI system is thus capable of generating 3D design objects that more accurately reflect the intents and design ideas for the larger 3D design project. In that regard, the disclosed techniques store one or more persistent intents that are associated with a larger 3D design project. Further, the disclosed techniques provide an automated process for generating composite prompts that include both inputs entered by the operator and the persistent intents. Adding the persistent intents to each of the prompts transmitted to the AI model enables the operator to clarify the overarching objectives, goals, and constraints for the larger 3D design project. Accordingly, the disclosed techniques enable the AI model to generate 3D design objects that are more responsive to the all the design intents of the operator. Accordingly, the disclosed techniques enable an operator of the CAD application to generate 3D design objects that align better with the larger 3D design project without requiring the operator to continually add the same detailed description to each prompt that the CAD application generates for the AI model. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design exploration application of FIG. 1, according to various embodiments;

FIG. 3 is a more detailed illustration of the design exploration application of FIG. 1 generating a prompt including a set of persistent intents, according to various embodiments;

FIG. 4 is an exemplar illustration of a prompt and multiple persistent intent descriptions displayed in the prompt space of FIG. 2, according to various embodiments;

FIG. 5 sets forth a flow diagram of method steps for generating digital content items, according to various embodiments; and

FIG. 6 depicts one architecture of a system within which embodiments of the present disclosure may be implemented.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

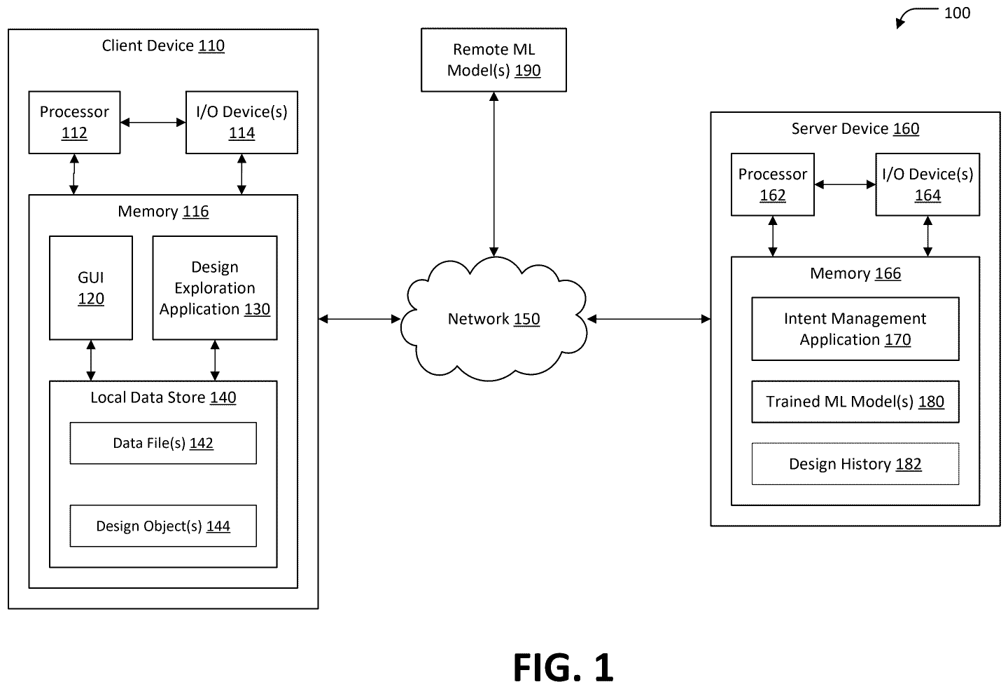

FIG. 1 is a conceptual illustration of a system 100 configured to implement one or more aspects of the various embodiments. As shown, in some embodiments, the system 100 includes, without limitation, a client device 110, a server device 160, and one or more remote machine learning (ML) models 190. The client device 110 includes, without limitation, a processor 112, one or more input/output (I/O) devices 114, and a memory 116. The memory 116 includes, without limitation, a graphical user interface (GUI) 120, a design exploration application 130, and a local data store 140. The local data store 140 includes, without limitation, one or more data files 142 and one or more design objects 144. The server device 160 includes, without limitation, a processor 162, one or more I/O devices 164, and a memory 166. The memory 166 includes, without limitation, an intent management application 170, one or more trained ML models 180, and design history 182. In some other embodiments, the system 100 can include any number and/or types of other client devices, server devices, remote ML models, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a client device. Some examples of client devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design exploration application 130 to generate designs for one or more 3D objects. In operation, the design exploration application 130 causes one or more ML models 180, 190 to synthesize designs for a 3D object based on any number of goals and constraints. The design exploration application 130 then presents the designs for the objects as one or more design objects 144 to an operator in the context of a design space. In some embodiments, the operator can explore and modify the one or more design objects via the GUI 120. Additionally or alternatively, the operator can also include at least one of the design objects 144 for use in additional design and/or manufacturing activities.

In various embodiments, the processor 112 can be any instruction execution system, apparatus, or device capable of executing instructions. For example, the processor 112 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, and so forth. In some embodiments, the I/O devices 114 also includes devices configured to provide output, including, for example, a display device, a speaker, and so forth. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design exploration application 130, and data (e.g., the data files 142 and/or the design objects stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design exploration application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design exploration application 130 resides in the memory 116 and executes on the processor 112 of the client device 110. The design exploration application 130 interacts with an operator via the GUI 120. In some embodiments, the design exploration application 130 and one or more separate applications (not shown) interact with the same operator via the GUI 120. In various embodiments, the design exploration application 130 operates as a 3D design application to generate and modify an overall 3D design for a larger 3D design project. The overall 3D design includes one or more design objects 144. The design exploration application 130 interacts with the operator via the GUI 120 in order to generate the one or more design objects 144 via direct user input (e.g., one or more tools to generate 3D objects, wireframe geometries, meshes, etc.) or via separate devices (e.g., the trained ML models 180, the remote ML models 190, separate 3D design applications, etc.). When generating the one or more design objects 144 via separate devices, the design exploration application 130 generates a prompt that effectively describes design-related intentions using one or more inputs of one or more modalities (e.g., text, speech, images, etc.). The design exploration application 130 then transmits the prompt to the one or more of the ML models 180, 190 and causes the one or more of the ML models 180, 190 to operate on the generated prompt to generate a relevant design object 144. The design exploration application 130 receives the design object 144 from the one or more ML models 180, 190 and displays the design object 144 within the GUI 120. The user can select via the GUI 120 the design object 144 for use, such as incorporating the design object 144 in a larger 3D design for a 3D design project.

In some embodiments, the design exploration application 130 can operate as another type of digital content creation (DCC) application. For example, the design exploration application 130 can operate as an image editor to generate and modify 2D or 3D images. In another example, the design exploration application 130 can operate as a video editor application that generates and modifies audiovisual content. When the design exploration application is operating as a DCC application, the design exploration application 130 interacts with a user via the GUI 120 in order to generate the one or more content items directly or via the ML models 180, 190. When generating content items via the ML models 180, 190, the design exploration application 130 generates a prompt that effectively describes design-related intentions for specific type of digital content item that is to be generated (e.g., describing aspects of a 2D image or sketch). The design exploration application 130 thus can generate various types of digital content items including, without limitation, a text, a computer-aided design (CAD) object, a geometry, an image, a sketch, a video, executable code, or an audio recording.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design exploration application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the design exploration application 130 organizes GUI elements into one or more container GUI elements (e.g., panels and/or panes).

In some embodiments, the GUI 120 includes one or more communications channels with one or more other devices and/or entities. For example, the design exploration application 130 can include a communication channel with the trained ML model 180 via the intent management application 170. As will be discussed in further detail below, the communication channel can be established between two or more client devices 110 (e.g., 110(1), . . . 110(X)) and one or more ML models 180 (e.g., 180(1), . . . 180(Y)) and/or one or more remote ML models 190 (e.g., 190(1), . . . 190(Z)).

The local data store 140 is a part of storage in the client device 110 that stores one or more design objects 144 included in a larger 3D design project and/or one or more data files 142 associated with 3D design. For example, a larger 3D design project for a building can include multiple stored design objects 144, including one or more design objects 144 that separately represent doors, windows, fixtures, walls, appliances, and so forth. The local data store 140 can also include data files 142 relating to a generated overall 3D design (e.g., component files, metadata, etc.). Additionally or alternatively, the local data store 140 includes data files 142 related to generating prompts for transmission to the one or more ML models 180, 190. For example, the local data store 140 can store one or more data files 142 for sketches, geometries (e.g., wireframes, meshes, etc.), images, videos, application states (e.g., camera angles used within a design space, tools selected by a user, etc.), audio recordings, and so forth. In some embodiments, the local data store 140 stores one or more digital content items created via the design exploration application 130. For example, the local data store 140 can store 2D images created directly by the user or generated by the one or more ML models 180, 190.

The design objects 144 are objects within the design space that are generated from designs generated by the one or more ML models 180, 190. The design objects 144 include geometries, textures, images, and/or other components that the design exploration application 130 uses to generate objects included in a larger 3D design project. In various embodiments, the geometry of a given design object 144 refers to any multi-dimensional model of a physical structure, including CAD models, meshes, and point clouds, as well as circuit layouts, piping diagrams, free-body diagrams, and so forth. In some embodiments, the design exploration application 130 stores multiple design objects 144 for a given 3D design and stores multiple iterations of a given target object that the ML models 180, 190. For example, the operator can form an initial prompt using the design exploration application 130 and receive a first generated design object 144(1) from the trained ML model 180(1), then refine the prompt and receive a second generated design object 144(2) from the trained ML model 180(1).

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design exploration application 130 to generate one or more design objects 144. In operation, the server device 160 executes the intent management application 170 to process a prompt generated by the design exploration application 130, select one or more ML models 180, 190 trained to generate design objects 144 in response to the contents of the prompt, and input the prompt into the selected ML models 180, 190. Once the selected ML models 180, 190 generate the design objects 144 that are responsive to the prompt, the server device 160 transmits the generated design objects to the client device 110, where the generated design objects 144 are usable by the design exploration application 130.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the intent management application 170 and one or more trained ML models 180, and data (e.g., the design history 182) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the intent management application 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the intent management application 170 could be executed on the client device 110 and can communicate with the trained ML models 180 operating at the server device 160.

In various embodiments, the intent management application 170 receives a prompt from the design exploration application 130 and inputs the prompt into an applicable ML model 180, 190. In some embodiments, the intent management application 170 maintains a multiparty interface (not shown) that serves as a communication channel between one or more client devices 110 and the ML models 180, 190. In such instances, the intent management application 170 and or the ML models 180, 190 participating in the multiparty interface can process inputs provided by the client devices 110 to determine whether the inputs include portions of prompts for the ML models 180, 190 to generate outputs. In some embodiments, one or more of the ML models 180, 190 are trained to respond to specific types of inputs, such as a ML model that is trained to generate design objects 144 from a specific combination of modalities (e.g., text and images). In such instances, the intent management application 170 processes a prompt to determine the modalities of the data that are included in the prompt and identifies one or more ML models 180, 190 that have been trained to respond to such a combination of modalities. Upon identifying the one or more ML models that are applicable, the intent management application 170 selects an ML model (e.g., the trained ML model 180(1)) and inputs the prompt into the selected ML model 180(1).

The trained ML models 180 include one or more generative ML models that have been trained on a relatively large amount of existing data and optionally any number of results (e.g., design objects 144 and evaluations provided by the user) to perform any number and/or types of prediction tasks based on patterns detected in the existing data. In various embodiments, the remote ML models 190 are trained ML models that communicate with the server device 160 to receive prompts via the intent management application 170. In some embodiments, the trained ML model 180 is trained using various combinations of data from multiple modalities, such as textual data, image data, sound data, and so forth. The trained ML model 180 and/or the remote ML model 190 trained using at least two modalities of data are also referred to herein as a multimodal ML model. For example, in some embodiments, the one or more trained ML models 180 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180 can be trained to generate design objects from various combinations of modalities. Such combinations include text, a CAD object, a geometry, an image, a sketch, a video, an application state, an audio recording, etc.).

The design history 182 includes data and metadata associated with the one or more trained ML models 180 and/or the one or more remote ML models 190 generating design objects 144 in response to prompts provided by the design exploration application 130. In some embodiments, the design history 182 includes successive iterations of design objects 144 that a single ML model 180 generates in response to a series of prompts. Additionally or alternatively, the design history 182 includes multiple design objects 144 that were generated by different ML models 180, 190 in response to the same prompt. In some embodiments, the design history 182 includes feedback provided by one or more users and/or one or more ML models 180, 190 (e.g., a ML model trained to output an evaluation of a design object) for a given design object 144. In such instances, the server device 160 can use the design history 182 as training data to further train the one or more ML models 180. Additionally or alternatively, the design exploration application 130 can retrieve contents of the design history 182 and display the retrieved contents to the user via the GUI 120.

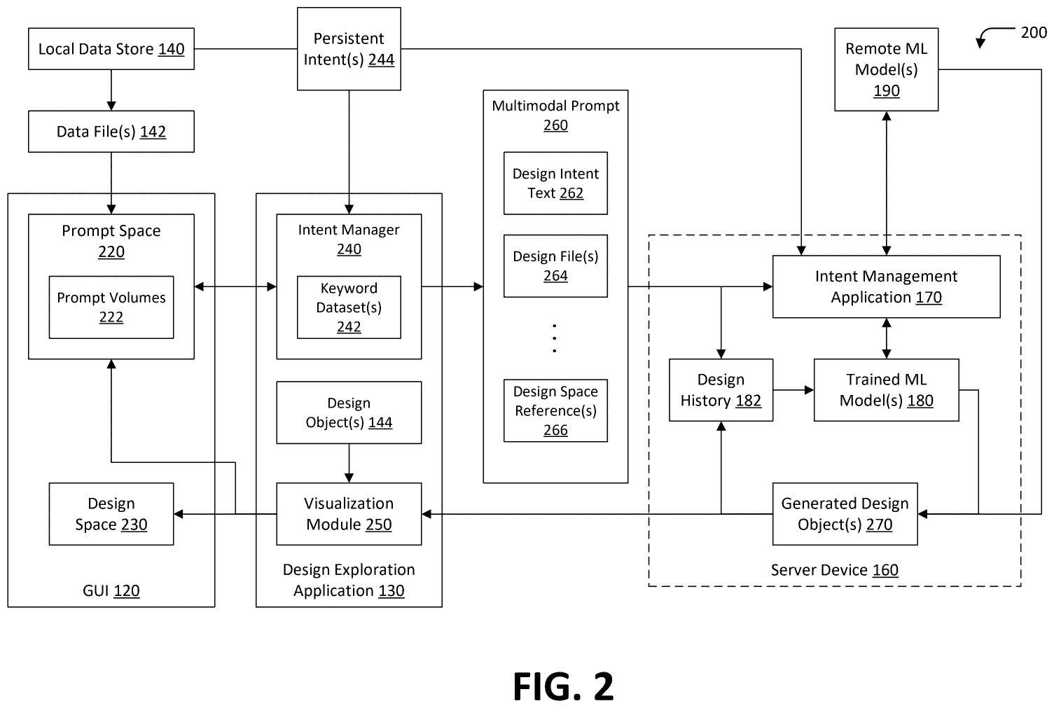

FIG. 2 is a more detailed illustration of the design exploration application 130 of FIG. 1, according to various embodiments. As shown, in some embodiments, the system 200 includes, without limitation, the GUI 120, the design exploration application 130, a local data store 140, the one or more data files 142, the server device 160, the remote ML models 190, one or more persistent intents 244, and a multimodal prompt 260. The GUI 120 includes, without limitation, a prompt space 220 including one or more prompt volumes 222, and a design space 230. The design exploration application 130 includes, without limitation, an intent manager 240 including one or more keyword datasets 242, the one or more design objects 144, and a visualization module 250. The server device 160 includes, without limitation, the intent management application 170, the one or more trained models 180, the design history 182, and one or more generated design objects 270. The multimodal prompt 260 includes, without limitation, design intent text 262, one or more design files 264, and one or more design space references 266.

For explanatory purposes only, the functionality of the design exploration application 130 is described herein in the context of exemplar interactive and linear workflows used to generate the generated design object 270 in accordance with user-based design-related intentions expressed during the workflow. The generated design object 270 includes, without limitation, one or more images, wireframe models, geometries, and/or meshes for use in a three-dimensional design, as well as any amount (including none) and/or types of associated metadata.

As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number of generated design objects 270 associated with any target content item in a linear fashion, a nonlinear fashion, an iterative fashion, a non-iterative fashion, a recursive fashion, a non-recursive fashion, or any combination thereof during an overall process for generating and evaluating designs for that target 3D object. A target 3D object can include any number (including one) and/or types of target content item and/or target content item components.

For example, in some embodiments, a generated design object 270 can be generated and displayed within the GUI 120 during a first iteration, any portion (including all) of the design object 270 can be selected via the GUI 120, and a first prompt multimodal prompt 260 can be set equal to the selected portion of the generated design object 270 to recursively generate a second generated design object 270 during a second iteration. In the same or other embodiments, the design exploration application 130 can display and/or re-display any number of GUI elements, generate and/or regenerate any amount of data, or any combination thereof any number of times and/in any order while generating each new generated design object 270.

In operation, the visualization module 250 of the design exploration application 130 provides the prompt space 220 and the design space 230 via the GUI 120. A user provides the contents for the multimodal prompt 260 via the prompt space 220. The design exploration application 130 processes the content to generate the multimodal prompt 260 and transmits the multimodal prompt 260 to the server device 160. The intent management application 170 identifies the modalities of the data included in the multimodal prompt 260 and identifies one or more trained ML models 180 and/or remote ML models 190 that have been trained to process the identified combination of modalities. The intent management application 170 inputs the multimodal prompt into one or more of the identified ML models 180, 190. The ML models 180, 190 respond to the multimodal prompt 260 by generating one or more design objects 270. The visualization module 250 receives the one or more generated design objects 270 and displays the one or more generated design objects 270 in the prompt space 220 and/or the design space 230.

In various embodiments, the design space 230 is a virtual workspace that includes one or more renderings of design objects (e.g., geometries of the design objects 144 and/or the generated design objects 270) that form an overall design for a content item (e.g., an overall 3D design). In some embodiments, the design space 230 includes multiple design alternatives for the larger 3D design project. For example, the design space 230 can graphically organize multiple designs that include differing combinations of design objects 144, 270. In such instances, the operator interacts with the GUI 120 to navigate between design alternatives to quickly analyze tradeoffs between different design options, observe trends in design options, constrain the design space 230, select specific design options, and so forth.

The prompt space 220 is panel or volume in which a user can generate prompts, such as the multimodal prompt 260 and/or the one or more prompt volumes 222. In some embodiments, the prompt space 220 is a panel, such as a window separate from the design space. For example, the prompt space 220 can include a multiparty interface (not shown) that communicates with the trained ML model 180 and/or one or more other client devices 110. Alternatively, in some embodiments, the prompt space 220 is a volume that is overlayed over at least a portion of the design space. In such instances, a user can invoke a prompt volume 222 and/or an input area for a multimodal prompt 260 at various locations within the design space 230.

The prompt volume 222 is a form of a prompt that executes operations within the boundaries of the volume. The prompt volume 222 is a volume within the design space that is defined by a corresponding prompt definition that specifies how objects appear and/or behave within the boundaries of the prompt volume 222. The prompt volume 222 exerts a “sphere of influence” (e.g., a volume of influence based on the boundaries) within the defined boundaries such that modifications made to the associated prompt definition causes changes to design objects within the boundaries. For example, the prompt definition enables the user to specify design intent text and/or non-textual inputs for objects that at least partially overlap the prompt volume 222. The prompt volume 222 a set of characteristics, including a spatial position (e.g., location and orientation), boundaries (defined via the textual definition or via user input within the prompt space 220), and shape (e.g., a sphere, a cuboid, a pyramid, an irregular 3D shape, etc.). In some embodiments, the prompt volume 222 includes weighted areas, weighted gradients, and/or linked prompt volumes (e.g., prompt volumes 222(1)-222(x)). In such instances, the linked prompted volumes include other overlapping prompt volumes and/or other prompt volumes linked in a hierarchy.

In various embodiments, when the user modifies the prompt volume 222, the prompt volume executes by updating one or more design objects 144, 270 that are within the sphere of influence of the prompt volume 222. For example, upon detecting a change to the prompt definition, the prompt volume 222 can receive a newly generated design object 270 and replace an existing design object 144 that is within the prompt volume 222. Additionally or alternatively, in some embodiments, the prompt volume 222 applies weighted values corresponding to the weighted areas and/or weighted gradients of the prompt volume. Upon executing the updates, the prompt volume 222 can cause the design exploration application 130 to generate a message indicating the change and “transmit” the message to other linked prompt volumes 222. In such instances, the prompt volumes 222 propagate changes among linked prompt volumes 222, which enables users to make modifications to multiple volumes within the design space 230 without applying global changes to the entire design space 230.

In various embodiments, the intent manager 240 determines the intent of inputs provided by the user. For example, the intent manager 240 can comprise a natural language (NL) processor that parses text included in the multimodal prompt 260. Additionally or alternatively, the intent manager 240 can include an audio processor that processes audio data to identify words included in audio data and parse the identified words. In some embodiments, the intent manager 240 is included in the intent management application 170 and/or the trained ML model 180. In such instances, the intent management application 170 and/or the trained ML model 180 can determine the intent of inputs provided by the operator via the multiparty interface and/or the one or more persistent intents 244 associated with the larger 3D design project.

In various embodiments, the intent manager 240 identifies one or more keywords in textual data. In some embodiments, the intent manager 240 includes one or more keyword datasets 242 that the intent manager 240 references when identifying the one or more keywords included in textual data. For example, the keyword datasets 242 can include, without limitation, a 3D keyword dataset that includes any number and/or types of 3D keywords, a customized keyword dataset that includes any number and/or types of customized keywords, and/or a user keyword dataset that includes any number and/or types of user keywords (e.g., words and/or phrases specified by a user). The keywords can comprise particular words or phrases (e.g., demonstrative pronouns, technical terms, referential terms, etc.) that are relevant to designing 3D objects. For example, a user can input a regular sentence (“I want a hinge to connect here”) within an input area within the prompt space 220. The intent manager identifies “hinge,” “connect,” and “here” as words relevant to the ML model 180, 190 generating a design object 270. In such instances, the intent manager 240 can update the prompt space 220 by highlighting the keywords, enabling the user to provide additional details (e.g., non-textual data) for inclusion in the multimodal prompt 260.

In various embodiments, the visualization module 250 displays the design space 230 and/or the prompt space 220 via the GUI 120. In some embodiments, the visualization module 250 updates the prompt space 220 and/or the design space 230 based on inputs entered by the operator and/or data received from the server device 160. For example, the visualization module 250 can initially detect the operator invoking a prompt via a hotkey or a marking menu within the prompt space 220. In such instances, the visualization module 250 can respond by displaying an input area to receive data to include in the multimodal prompt 260. When the operator initially inputs a textual phrase, the visualization module 250 can respond to the intent manager 240 identifying one or more keywords by updating the input area to highlight the keywords and/or display contextual input areas proximate to at least one keyword. In this manner, the design exploration application 130 iteratively receives multiple modalities of input data to include into the multimodal prompt 260. In some embodiments, the visualization module 250 can display one or more panels representing the one or more persistent intents 244 that are to be included in the multimodal prompt 260.

In various embodiments, the design exploration application 130 receives textual and/or non-textual data to include in the multimodal prompt 260 via the input areas included in the prompt space 220. When providing non-textual data, the operator can retrieve stored data, such as one or more stored data files 142 (e.g., stored geometries, stored CAD files, audio recordings, stored sketches, etc.) from the local data store 140. Additionally or alternatively, the operator can retrieve contents from the design history 182 and can add the contents into the input area. In such instances, the contents from the design history 182 is stored in one or more data files 142 that the user retrieves from the local data store 140.

The multimodal prompt 260 is a prompt that includes two or more modalities of data (e.g., textual data, image data, audio data, etc.) that specifies the design intent of the user. In various embodiments, the design exploration application 130 receives multiple types of data and builds the multimodal prompt 260 to include each of the multiple types of data. For example, the operator can initially write design intent text 262 that refers to a sketch. The design exploration application 130 then receives a sketch (e.g., a stored sketch or a sketch the user inputs into an input design area). Upon receiving the sketch, the design exploration application 130 can then generate the multimodal prompt 260 to include both the design intent text 262 and the sketch. In some embodiments, the multimodal prompt 260 can include multiple data inputs of the same modality. For example, the multimodal prompt 260 can include multiple design intent texts 262 (e.g., 262(1), 262(2), etc.) and/or multiple design files 264 (e.g., 264(1), 264(2), etc.). As will be discussed in further detail below, the design exploration application 130 can also weigh each component of the multimodal prompt 260. For example, the design exploration application 130 can weigh each component of the multimodal prompt 260 (e.g., 0.8 to each input provided by the operator, 0.2 to each persistent intent 244). Alternatively, the design exploration application 130 can weigh each component of the multimodal prompt 260 individually (e.g., 0.4 to the design intent text 262(1), 0.1 to a sketch, and 0.5 to the persistent intent 244).

Additionally or alternatively, in some embodiments, the intent management application 170 can generate the multimodal prompt 260. For example, a first user can initially write design intent text 262 to the multiparty interface. A second user can then provide a sketch to the multiparty interface. Upon receiving the sketch, the intent management application 170 can then generate the multimodal prompt 260 to include both the design intent text 262 and the sketch.

The design intent text 262 includes textual data that describes the design intent. In various embodiments, the design intent text 262 can include textual inputs entered by the operator and one or more textual descriptions included in the one or more persistent intents 244. For example, the design intent text can include descriptions for characteristics of a target 3D design object (e.g., “a handle made of titanium”). In some embodiments, the design exploration application 130 generates the design intent text 262 from a different type of data input. For example, the intent manager 240 can perform NL processing to identify words included in an audio recording. In such instances, the design exploration application 130 generates the design intent text 262 that includes the identified words.

The design files 264 includes one or more files (e.g., CAD files, stored text, audio recordings, stored geometries, etc.) that the user adds to be included in the multimodal prompt 260. In some embodiments, the design files 264 can include textual data (e.g., textual descriptions, physical dimensions, etc.). In various embodiments, an operator can add multiple design files 264 to include in the multimodal prompt 260. In some embodiments, the design exploration application 130 converts various types of data into the design files 264. For example, the operator can record audio via the input area. In such instances, the design exploration application 130 can store audio recording as a design file 264. The design files 264 can include one or more modalities (e.g., textual data, video data, audio data, image data, etc.).

In some embodiments, the design space references 266 can include one or more references to the prompt space 220 and/or the design space 230. For example, the user can input text that references a specific application state (e.g., “make the thing selected by the current tool lighter,” “generate a seat for the car in this view,” etc.). In such instances, the design exploration application 130 determines the application state the user is referencing. The design exploration application 130 can then include the reference in the multimodal prompt 260 as the design space reference 266.

In various embodiments, the intent management application 170 receives and processes the multimodal prompt 260 to identify the modalities of the contents of the multimodal prompt 260. For example, the intent management application 170 the modalities of the design intent text 262, the one or more design files 264, and/or the one or more design space references 266 included in the multimodal prompt 260. For example, the intent management application 170 can identify a combination of text, image, and video modalities included in the multimodal prompt. The intent management application 170 identifies at least one ML model 180, 190 that was trained with that combination of modalities and selects one of the identified ML models 180, 190. The intent management application 170 executes the selected ML model by inputting the multimodal prompt 260 into the selected ML model. The selected ML model generates a design object 270 in response to the multimodal prompt 260. In some embodiments, the server device 160 includes the generated design object 270 in the design history 182. In such instances, the generated design object 270 is a portion of the design history 182 used as training data to train one or more trained ML models 180 (e.g., further training the selected ML model, training other ML models, etc.).

### Persistent Prompts for Generative Artificial Intelligence Systems

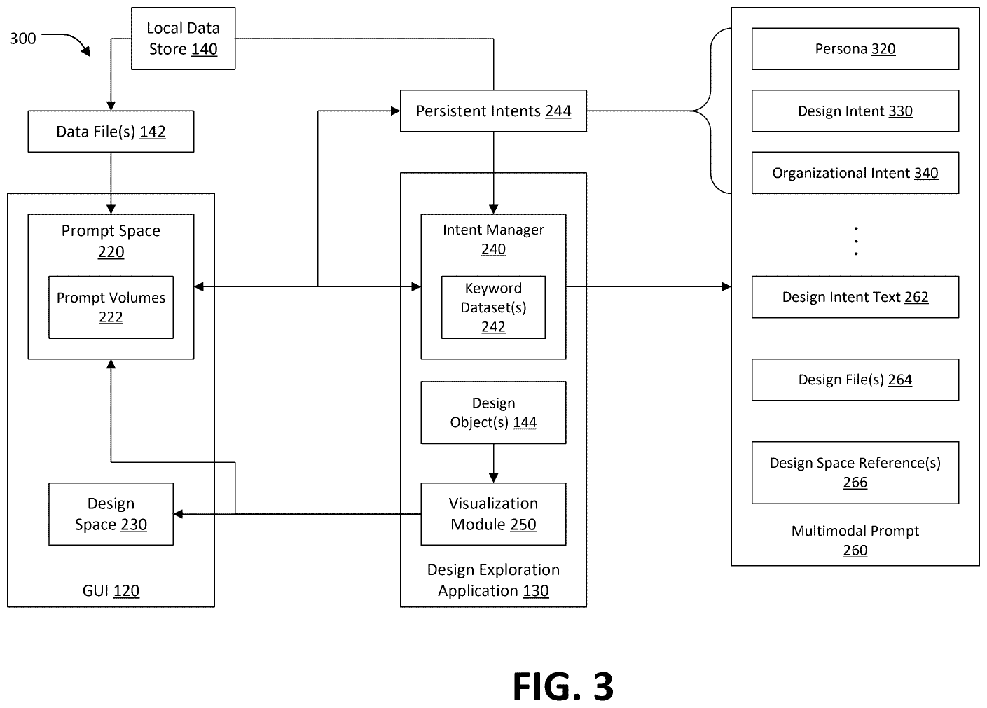

FIG. 3 is a more detailed illustration of the design exploration application 130 of FIG. 1 generating a prompt including a set of persistent intents, according to various embodiments. As shown, in some embodiments, the system 300 includes, without limitation, the GUI 120, the design exploration application 130, the local data store 140, the one or more data files 142, the one or more persistent intents 244, and the multimodal prompt 260. The GUI 120 includes, without limitation, a prompt space 220 including one or more prompt volumes 222, and a design space 230. The design exploration application 130 includes, without limitation, the intent manager 240 including one or more keyword datasets 242, the one or more design objects 144, and a visualization module 250. The server device 160 includes, without limitation, the intent management application 170, the one or more trained models 180, the design history 182, and one or more generated design objects 270. The multimodal prompt 260 includes, without limitation, a persona 320, a design intent 330, and an organizational intent, the design intent text 262, the one or more design files 264, and the one or more design space references 266.

In operation, the operator provides the content for the multimodal prompt 260 via the prompt space 220. The design exploration application 130 processes the content provided by the operator and the persistent intents 244 to generate the multimodal prompt 260. The multimodal prompt 260 includes one or more persistent intents 244, the persona 320, the design intent 330, and/or the organizational intent 340, stored in the local data store 140. The design exploration application 130 transmits the multimodal prompt 260 to the server device 160 for input into a trained ML model 180, 190. The ML models 180, 190 respond to the multimodal prompt 260 by generating one or more design objects 270 that are responsive to contents of the multimodal prompt 260, including one or more of the persona 320, the design intent 330, or the organizational intent 340.

The persona 320 is associated with the operator of the client device 110. In various embodiments, the persona 320 reflects one or more parameters and/or preferences of the operator. For example, the persona 320 can identify a job of the first operator, demographic information (e.g., age, gender, sex, experience, group member designation, etc.). Additionally or alternatively, in some embodiments, the persona specifies one or more preferences of the operator. For example, the persona 320 can include one or more settings specified by the user and/or a description of preferences associated with the user and/or usage patterns of the operator (e.g., “uses keyboard shortcuts and key bindings,” “prefers comparison of 3 designs”)

In various embodiments, the design exploration application 130 generates the persona 320 based on the usage pattern of the operator during one or more sessions using the design exploration application 130. In such instances, the design exploration application 130 retrieves historical data from the client device 110 and/or the server device 160 that includes the usage patterns. In some embodiments, the design exploration application 130 processes the usage patterns to generate a description to include the persona 320. For example, the design exploration application 130 can classify the operator as one of plurality of a preexisting personas based the usage pattern (e.g., “novice user,” etc.). In such instances, the design exploration application 130 can classify the operator and store a description for the preexisting persona as part of the persona 320. Additionally or alternatively, in some embodiments, the design exploration application 130 causes an applicable trained ML model 180, 190 (e.g., the remote ML model 190(1)) to generate a persona description based on the usage pattern. The trained ML 180, 190 can be a separate ML model 180, 190 than the trained ML model 180, 190 that generates the design objects 270 in response to the multimodal prompt 260. In such instances, the design exploration application 130 transmits the usage pattern to the applicable trained ML model 190(1) and receives a textual description from the trained ML model 190(1). The design exploration application 130 can then store the received textual description as the persona description 422.

The design intent 330 includes a description and/or non-textual data that corresponds to the CAD design and is entered by the operator of the first client device. In various embodiments, the operator can enter a textual description specifying intermediate and/or long-term design goals, constraints, and objectives for the larger 3D design project. For example, the operator can specify a specific objective (e.g., “generate comfortable seating”) and/or an overarching objective (e.g., “use sustainable materials”) as the design intent 330. In such instances, the design exploration application 130 can include the one or more objectives as portions of the design intent 330 that are included in each multimodal prompt 260 that the design exploration application 130 transmits to the trained ML model 180, 190. In various embodiments, the design intent 330 can include non-textual data, such as one or more 2D or 3D designs that corresponds to the larger 3D design project. In such instances, the design exploration application 130 can include the non-textual data as a component of the design intent 330 included in the multimodal prompt 260.

The organizational intent 340 includes a description and/or non-textual data that corresponds to the CAD design and is received by a group of operators that includes the operator of the client device 110 (e.g., the client device 110(1)). For example, the operator can be a member of a group that includes a design leader that distributes the organizational intent 340. In such instances, the client device 110 can store the organizational intent 340 transmitted from a separate client device (e.g., the client device 110(2)). In some embodiments, the design leader that generated the organizational intent 340 can lock the organizational intent 340. In such instances, the operator, the client device 110(1), and/or other group members can be locked from modifying the organizational intent 340. In various embodiments, the organizational intent 340 can include non-textual data, such as one or more 2D or 3D designs that corresponds to the larger 3D design project. In such instances, the design exploration application 130 can include the non-textual data as a component of the organizational intent 340 included in the multimodal prompt 260.

In various embodiments, the design exploration application 130 generates a composite prompt by applying weights to one or more components of the multimodal prompt 260. In some embodiments, the weighting can be designated based on the type of component. For example, each persistent intent 244 can have the same weight value (e.g. 0.2). In such instances, the design exploration application 130 weighs each component of the multimodal prompt 260 by applying a specific weight value corresponding to each type of component (e.g., 0.8 to each input entered by the operator, 0.2 to each persistent intent 244). Alternatively, in some embodiments, the weight values are applied based on relative priority, such as applying the greatest weight value to the organizational intent 340 and applying smaller weight values to other persistent intents 244 and/or inputs entered by the operator. Alternatively, the design exploration application 130 can weigh each component of the multimodal prompt 260 individually (e.g., 0.4 to the design intent text 262(1), 0.1 to a sketch, and 0.5 to the persistent intent 244).

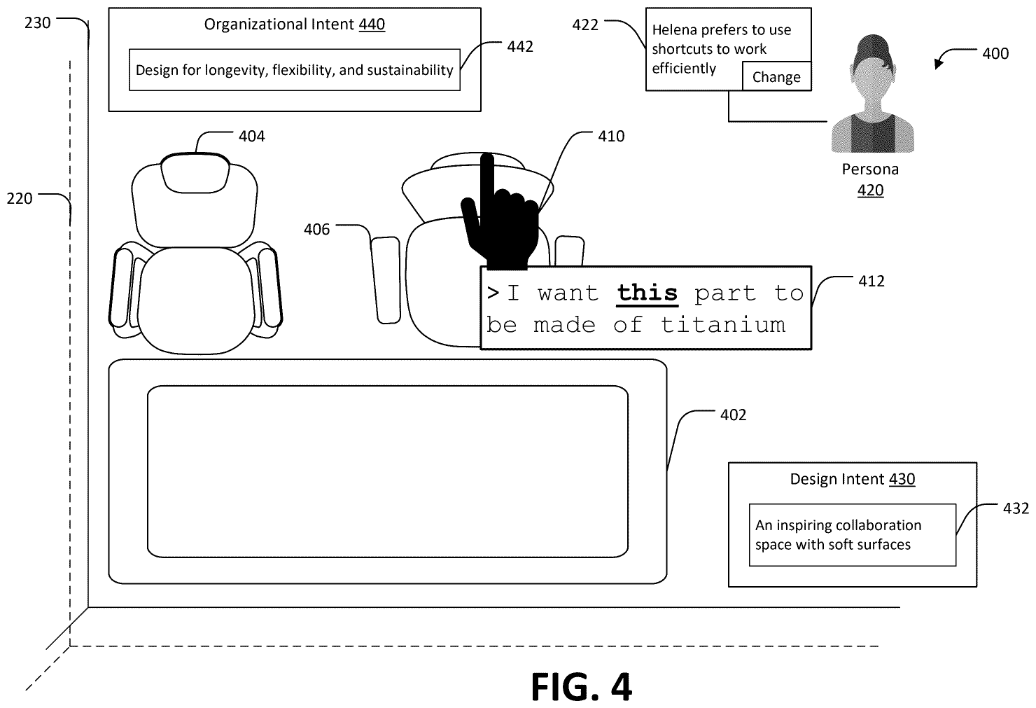

FIG. 4 is an exemplar illustration of a prompt 412 and multiple persistent intent descriptions 422, 432, 442 displayed in the prompt space 230 of FIG. 2, according to various embodiments. As shown, the visualization 400 includes, without limitation, the prompt space 220, the design space 230, a plurality of geometries 402-404, a cursor 410, a prompt input area 412, and persistent intent panels 420-440. The persona intent panel 420 includes, without limitation, persona description 422. The design intent panel 430 includes, without limitation, design intent description 432. The organizational intent panel 440 includes, without limitation, organizational intent description 442.

In various embodiments, the visualization module 250 of the design exploration application 130 displays a visualization 400 of the design space 230 and the prompt space 220 via the GUI 120. As shown, the visualization 400 displays a unified prompt space, where the prompt space 220 is overlayed over the design space 230. In such instances, the design exploration application 130 can place the plurality of intent panels 420, 430, 440 at various locations within the unified prompt space. Additionally or alternatively, the user can toggle the display of one or more of the intent panels 420, 430, 440 through specific user actions (e.g., one or more visualization toggles or gestures).

The design space 230 is a volumetric space that displays one or more geometries of design objects 144 that are part of a larger 3D design project. The design space 230 can include two-dimensional (e.g., panels, textures, overlays, etc.) and/or three-dimensional content. In various embodiments, the design exploration application 130 enables the user to manipulate a camera within the design space 230 using one or more tools (not shown) to control the roll, pitch, yaw, zoom level, etc., of the camera. Additionally or alternatively, the design exploration application 130 includes controls to sketch images, create new geometries 402-406 and textures and/or edit the existing geometries. In various embodiments, the design space 230 can include multiple geometries 402-406 that combine to form an overall 3D design. For example, the design space 230 can include a plurality of components (e.g., a geometry for a table 402, geometries for chairs 404-406, etc.) that are included in an larger 3D design project for a conference room.

The prompt space 220 is a volume that displays one or more records included in the prompt history and enables the user to generate prompts that are usable to interact with the ML models 180, 190. In various embodiments, the prompt space 220 overlays at least a portion of the design space 230. Alternatively, in some embodiments, the prompt space 220 is a separate than the volume forming the design space 230. In various embodiments, the user can invoke a prompt (e.g., a prompt input area 412 and/or a prompt volume 222) via a hotkey or a menu within the prompt space 220. For example, the user can select a tool (not shown) to draw the prompt volume 222(2). In another example, the user can invoke the prompt input area 412 proximate to the location of the cursor 410. In such instances, the user can add textual data to the prompt input area 412 to enter a textual user input.

In various embodiments, the design exploration application 130 can display one or more intent panels 420, 430, 440 within the prompt space 220. For example, as shown, the prompt space 220 includes a virtual wall on which the intent panels 420, 430, 440 are displayed. Alternatively, the intent panels 420, 430, 440 can be seen as floating within the prompt space and can be moved and/or hidden via the cursor 410.

In various embodiments, the local data store 140 stores contents (e.g., the persistent intents 244) for one or more existing intent panels 420, 430, 440. In such instances, the design exploration application 130 can retrieve the persistent intents 244 and include at least a portion of the persistent intents 244 in the applicable intent panels 420, 430, 440. The design exploration application 130 can then display the existing intent panels 420, 430, 440 in the prompt space 220.

In various embodiments, the operator interacts with one or more of the intent panels 420, 430, 440 directly. In some embodiments, the operator enters feedback for at least one of the persistent intents 244 displayed via the intent panels 420, 430, 440. For example, a user can select an intent panel and select the panel or a specific interactive element (e.g., the “change” button) to modify a specific persistent intent 244. For example, the operator can select a portion of the persona intent panel 420 to change the avatar representing the operator and can retype a new description to replace the persona description 422. In such instances, the design exploration application 130 updates the applicable persistent intent 244 based on the feedback.

In some embodiments, the user can enter feedback that reflects the responsiveness of a design object 270 to the one or more persistent intents 244. In such instances, the design exploration application 130 can transmit the feedback to the trained ML model 180, 190. For example, upon the visualization displaying the geometry for the table 402, the operator can select the geometry 402 and can enter one or more inputs of positive or negative feedback that indicates whether the geometry is responsive to one or more of the intent descriptions 422, 432, 442. In such instances, the trained ML model 180, 190 can then incorporate the feedback into subsequent designs that includes the same persistent intents 244.

In some embodiments, the operator can specify weight values for the persistent intents 244 via the GUI 120. For example, in some embodiments, the prompt space 220 can include a priority panel (not shown) that lists each of the respective persistent intent. In such instances, the overall order of the persistent intents in the priority panel specifies relative priority, where the first persistent intent listed has priority the second persistent intent, and so forth. In some embodiments, the design exploration application 130 can apply relative weight values based on the order of the priority panel, where the greatest weight value is applied to the first listed persistent intent, where the second greatest weight value is applied to the second listed persistent intent, and so forth.

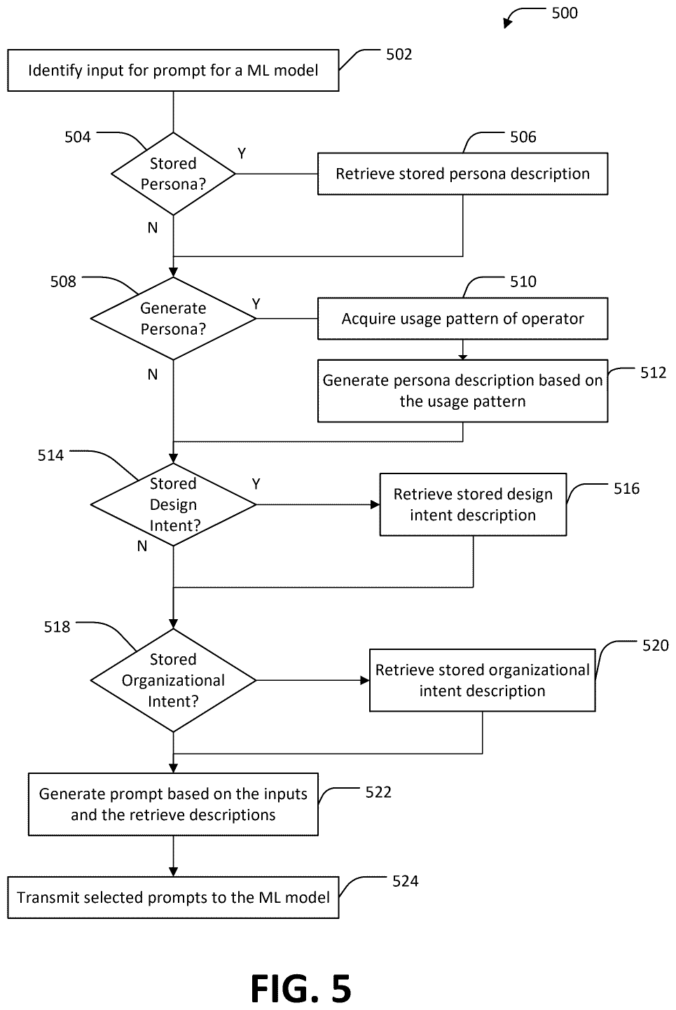

FIG. 5 sets forth a flow diagram of method steps for generating digital content items, according to various embodiments. Although the method steps are described with reference to the systems of FIGS. 1-4 and 6, persons skilled in the art will understand that any system configured to implement the method steps, in any order, falls within the scope of the embodiments.

A method 500 begins at step 502, where the design exploration application 130 identifies an input for a ML model. In various embodiments, the design exploration application 130 detects an input entered by an operator and responds by generating a prompt input area 412 within the prompt space 220. In some embodiments, the prompt space 220 at least partially overlays the design space 230. In such instances, the operator can invoke prompt input area 412 for the multimodal prompt 260 at various locations within the design space 230. In some embodiments, the prompt input area 412 enables the operator to enter data, such as text and/or non-textual data. Additionally or alternatively, in some embodiments, the design exploration application 130 may generate a prompt volume within the design space 230.

At step 504, the design exploration application 130 determines whether the client device 110 is storing a persona 320. In various embodiments, the design exploration application 130 determines whether the local data store 140 is storing a persona 320, where the persona 320 includes a persona description 422 description on or more design parameters associated with the operator (e.g., job description, age, usage patterns, preferences, etc.). When the design exploration application 130 identifies the persona description 422, the design exploration application 130 proceeds to the step 506, where the design exploration application 130 retrieves the stored persona description 422. Otherwise, the design exploration application does not identify the persona description 422 and proceeds to step 508.

At step 508, the design exploration application 130 determines whether to generate a persona 320. In various embodiments, the design exploration determines whether to generate a persona 320 to reflect the operator generating the larger 3D design project. For example, the design exploration application 130 can determine that the local data store 140 is not storing any persona 320. In another example, the design exploration application 130 can determine that the operator has entered one or more inputs to change and/or overwrite an existing persona 320. When the design exploration application 130 determines to generate a persona 320, the design exploration application 130 proceeds to step 510. Otherwise, the design exploration application 130 determines not to generate a persona 320 and proceeds to step 514.

At step 510, the design exploration application 130 acquires the usage pattern of the operator. In various embodiments, the design exploration application 130 generates the persona 320 based on the usage pattern of the operator during one or more sessions using the design exploration application 130. In such instances, the design exploration application 130 retrieves historical data from the client device 110 and/or the server device 160 that includes the usage patterns of the operator.

At step 512, the design exploration application 130 generates a persona description based on the usage pattern. In various embodiments, the design exploration application 130 can process the usage patterns to generate the persona description 422 to include the persona 320. For example, the design exploration application 130 can use the usage pattern to classify the operator as one of plurality of a preexisting personas (e.g., “uses keyboard shortcuts and key bindings,” etc.). In such instances, the design exploration application 130 can classify the operator and store a description for the preexisting persona as the persona description 422. Additionally or alternatively, in some embodiments, the design exploration application 130 causes an applicable trained ML model 180, 190 (e.g., the remote ML model 190(1)) to generate a persona description based on the usage pattern. In such instances, the design exploration application 130 transmits the usage pattern to the applicable trained ML model 190(1) and receives a textual description from the trained ML model 190(1). The design exploration application 130 can then store the received textual description as the persona description 422.

At step 514, the design exploration application 130 determines whether the client device 110 is storing a design intent 330. In various embodiments, the design exploration application 130 determines whether the local data store 140 is storing a design intent 330, where the design intent 330 includes a design intent description 432 that describes the contextual goal or setting specified by the operator for generating design objects for the larger 3D design project. When the design exploration application 130 identifies the design intent description 432, the design exploration application 130 proceeds to the step 516, where the design exploration application 130 retrieves the stored design intent description 432. Otherwise, the design exploration application does not identify the design intent description 432 and proceeds to step 518.

At step 518, the design exploration application 130 determines whether the client device 110 is storing an organizational intent 340. In various embodiments, the design exploration application 130 determines whether the local data store 140 is storing an organizational intent 340, where the organizational intent 340 includes an organizational intent description 442 that describes objectives, goals, and constraints for a group of operators when generating the larger 3D design project. When the design exploration application 130 identifies the organizational intent description 432, the design exploration application 130 proceeds to the step 520, where the design exploration application 130 retrieves the stored organizational intent description 442. Otherwise, the design exploration application does not identify the organizational intent description 442 and proceeds to step 522.

At step 522, the design exploration application 130 generates a prompt. In various embodiments, the design exploration application 130 generates the multimodal prompt 260 for transmission to the one or more trained ML models 180, 190. In various embodiments, the design exploration application 130 generates the multimodal prompt 260 to include a plurality of components, such as one or more inputs entered by the operator, and one or more of the persistent intents 244. In such instances, the persistent intents 244 can be textual data (e.g., the descriptions 422, 432, 442) or non-textual data. In various embodiments, the multimodal prompt 260 can include at least two modalities. For example, the design exploration application 130 can generate a multimodal prompt 260 that includes at least the design intent text 262 and at least one design file 264 comprising video data.

In some embodiments, the design exploration application 130 determines whether to apply weights to the components of the multimodal prompt 260. In various embodiments, the intent management application 170 determines whether to apply weight values to the components of the multimodal prompt 260. In such instances, the design exploration application 130 applies weight values to each of the components that are included in the multimodal prompt. For example, the design exploration application 130 can retrieve weight values that are designated to the specific types of input and intent (e.g., 0.35 to the design intent text 262, 0, and 0.5 to the organizational intent description 442, 0.1 to the design intent description 432, and 0.05 to the persona description 422). The design exploration application 130 can then apply the weight value to each component of the multimodal prompt 260.

At step 524, the design exploration application 130 transmits the prompt to the ML model 180, 190. In various embodiments, the design exploration application transmits the multimodal prompt 260 to an applicable ML model (e.g., the trained ML model 180(1)). In various embodiments, the design exploration application 130 causes the server device 160 to execute the trained ML model 180(1) using the multimodal prompt 260 as an input to generate the design object 270. In various embodiments, one or more trained ML models 180 local to the server device 160 and/or one or more remote ML devices 190 are trained using multimodal prompts. In such instances, the intent management application 170 operating on the server device 160 can identify the combination of modalities included in the multimodal prompt 260 and selects an applicable ML model 180(1) that was trained using the identified combination of modalities. The intent management application 170 inputs the multimodal prompt 260 into the selected ML model 180(1). In various embodiments, the selected ML model 180(1) generates a design object 270 based on the plurality of components included in the multimodal prompt 260, including the one or more persistent intents 244.

In various embodiments, the server device 160 receives the generated design object 270 from the selected ML model 180(1) and transmits the generated design object 270 to the client device 110. In such instances, the design exploration application 130 receives the generated design object 270 and causes the client device 110 to store the generated design object 270 in the local data store 140. The design exploration application 130 can then add the generated design object 270 to the design space 230. In various embodiments, the visualization module 250, upon receiving the generated design object 270, adds the generated design object to a location in the design space 230 for viewing via the GUI 120. In some embodiments, the prompt space 220 is separate from the design space 230. In such instances, the visualization module 250 can display the generated in the prompt space 220 in lieu of or in addition to displaying the generated design object 270 in the design space 230.

### System Implementation

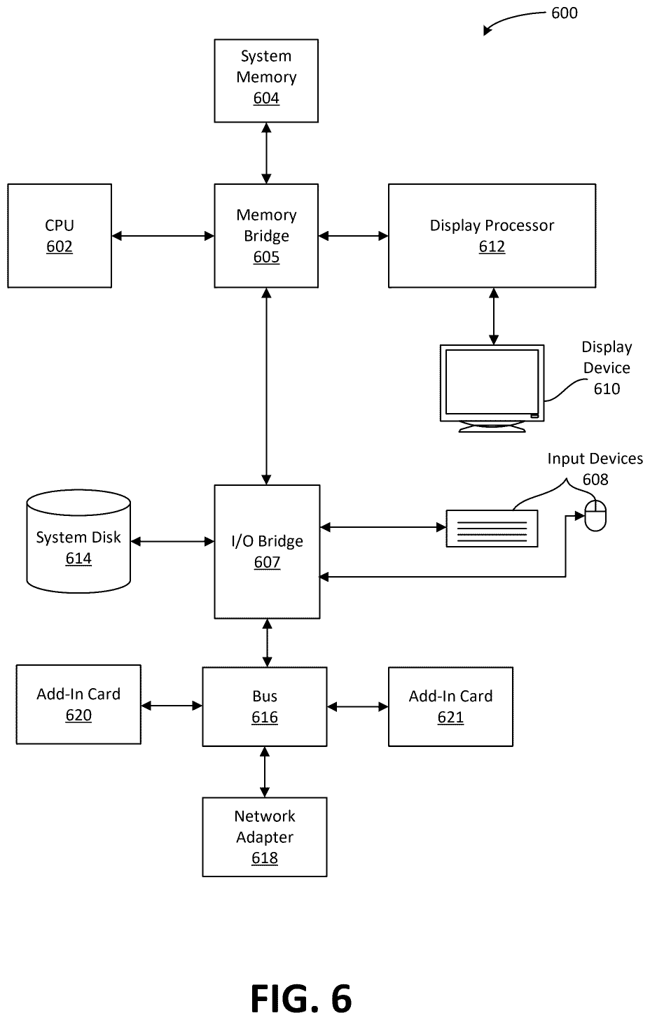

FIG. 6 depicts one architecture of a system 600 within which embodiments of the present disclosure may be implemented. This figure in no way limits or is intended to limit the scope of the present disclosure. In various implementations, system 600 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 600 may be coupled together to practice one or more aspects of the present disclosure.

As shown, system 600 includes a central processing unit (CPU) 602 and a system memory 604 communicating via a bus path that may include a memory bridge 605. CPU 602 includes one or more processing cores, and, in operation, CPU 602 is the master processor of system 600, controlling and coordinating operations of other system components. System memory 604 stores software applications and data for use by CPU 602. CPU 602 runs software applications and optionally an operating system. Memory bridge 605, which may be, e.g., a Northbridge chip, is connected via a bus or other communication path (e.g., a HyperTransport link) to an I/O (input/output) bridge 607. I/O bridge 607, which may be, e.g., a Southbridge chip, receives user input from one or more user input devices 608 (e.g., keyboard, mouse, joystick, digitizer tablets, touch pads, touch screens, still or video cameras, motion sensors, and/or microphones) and forwards the input to CPU 602 via memory bridge 605.

A display processor 612 is coupled to memory bridge 605 via a bus or other communication path (e.g., a PCI Express, Accelerated Graphics Port, or HyperTransport link); in one embodiment display processor 612 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 604.

Display processor 612 periodically delivers pixels to a display device 610 (e.g., a screen or conventional CRT, plasma, OLED, SED or LCD based monitor or television). Additionally, display processor 612 may output pixels to film recorders adapted to reproduce computer generated images on photographic film. Display processor 612 can provide display device 610 with an analog or digital signal. In various embodiments, one or more of the various graphical user interfaces set forth in Appendices A-J, attached hereto, are displayed to one or more users via display device 610, and the one or more users can input data into and receive visual output from those various graphical user interfaces.

A system disk 614 is also connected to I/O bridge 607 and may be configured to store content and applications and data for use by CPU 602 and display processor 612. System disk 614 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 616 provides connections between I/O bridge 607 and other components such as a network adapter 618 and various add-in cards 620 and 621. Network adapter 618 allows system 600 to communicate with other systems via an electronic communications network, and may include wired or wireless communication over local area networks and wide area networks such as the Internet.

Other components (not shown), including USB or other port connections, film recording devices, and the like, may also be connected to I/O bridge 607. For example, an audio processor may be used to generate analog or digital audio output from instructions and/or data provided by CPU 602, system memory 604, or system disk 614. Communication paths interconnecting the various components in FIG. 6 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 612 incorporates circuitry optimized for graphics and video processing, including, for example, video output circuitry, and constitutes a graphics processing unit (GPU). In another embodiment, display processor 612 incorporates circuitry optimized for general purpose processing. In yet another embodiment, display processor 612 may be integrated with one or more other system elements, such as the memory bridge 605, CPU 602, and I/O bridge 607 to form a system on chip (SoC). In still further embodiments, display processor 612 is omitted and software executed by CPU 602 performs the functions of display processor 612.

Pixel data can be provided to display processor 612 directly from CPU 602. In some embodiments of the present disclosure, instructions and/or data representing a scene are provided to a render farm or a set of server computers, each similar to system 600, via network adapter 618 or system disk 614. The render farm generates one or more rendered images of the scene using the provided instructions and/or data. These rendered images may be stored on computer-readable media in a digital format and optionally returned to system 600 for display. Similarly, stereo image pairs processed by display processor 612 may be output to other systems for display, stored in system disk 614, or stored on computer-readable media in a digital format.

Alternatively, CPU 602 provides display processor 612 with data and/or instructions defining the desired output images, from which display processor 612 generates the pixel data of one or more output images, including characterizing and/or adjusting the offset between stereo image pairs. The data and/or instructions defining the desired output images can be stored in system memory 604 or graphics memory within display processor 612. In an embodiment, display processor 612 includes 3D rendering capabilities for generating pixel data for output images from instructions and data defining the geometry, lighting shading, texturing, motion, and/or camera parameters for a scene. Display processor 612 can further include one or more programmable execution units capable of executing shader programs, tone mapping programs, and the like.

Further, in other embodiments, CPU 602 or display processor 612 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 602, display processor 612, or one or more other processing devices or any combination of these different processors.

CPU 602, render farm, and/or display processor 612 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 600 may be a robot or robotic device and may include CPU 602 and/or other processing units or devices and system memory 604. In such embodiments, system 600 may or may not include other elements shown in FIG. 1. System memory 604 and/or other memory units or devices in system 600 may include instructions that, when executed, cause the robot or robotic device represented by system 600 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 604 is connected to CPU 602 directly rather than through a bridge, and other devices communicate with system memory 604 via memory bridge 605 and CPU 602. In other alternative topologies display processor 612 is connected to I/O bridge 607 or directly to CPU 602, rather than to memory bridge 605. In still other embodiments, I/O bridge 607 and memory bridge 605 might be integrated into a single chip. The particular components shown herein are optional; for instance, any number of add-in cards or peripheral devices might be supported. In some embodiments, switch 616 is eliminated, and network adapter 618 and add-in cards 620, 621 connect directly to I/O bridge 607.

In sum, the disclosed techniques can be used to generate 3D design objects based on design intentions expressed by both inputs entered by operators via a GUI, as well as persistent design intents stored in a local data store. In various embodiments, a design exploration application causes the local data store to store one or more persistent intents associated with a larger 3D design project. The persistent intents include at least one of (i) a persona description that specifies the job, usage patterns, and preferences of the operator of the design exploration application; (ii) a design intent that describes the contextual goal or setting specified by the operator for generating design objects for the larger 3D design project; and (iii) an organizational intent that describes objectives, goals, and constraints for a group of operators when generating the larger 3D design project. The design exploration application generates a prompt space for a user to generate a prompt. The prompt space overlaps the design space, where a user can invoke a prompt anywhere in the design space. Alternatively, in some embodiments, the prompt space is separate from the design space. The design exploration application responds to an input in the prompt space by generating a prompt input area within the prompt space. The operator adds textual inputs and/or non-textual inputs to the prompt input area. Upon receiving the one or more inputs from the operator, the design exploration application generates a composite prompt that includes the inputs entered by the operator and the one or more persistent intents retrieved from the local data store. In some embodiments, design exploration application prioritizes a specific persistent intent or an specific input entered by the operator such as by applying one or more weight values to the inputs or persistent intents included in the prompt. In such instances, the design exploration application generates a weighted composite prompt based on the inputs, the persistent intents, and the weight values. The design exploration application transmits the composite prompt to an intent management application operating at a server device.

Upon receipt, the intent management application identifies one or more AI models that are trained to process the composite prompt. The intent management application inputs the composite prompt to the identified AI model. The AI model can be local or remote to the server device. The AI model, trained using histories of prompts, generated digital content items (e.g., 3D design objects), and evaluations of the generated digital content items, generates a 3D design object that is responsive to the composite prompt. In some embodiments, the AI model generates a single 3D design object that is usable in a design project. Alternatively, in some embodiments, the generative AI model generates a plurality of 3D design objects. Each of the generated 3D design objects adheres to the characteristics specified by the composite prompt. The design exploration application receives the one or more generated 3D design objects from the server device and displays the one or more generated 3D design objects via the GUI.

At least one technical advantage of the disclosed techniques relative to the prior art is that the disclosed techniques can be used to enable a CAD application to combine inputs entered by an operator with one or more intents associated with a larger 3D design project. Inclusion of the such intents in the prompts that are transmitted to an AI system allows the AI system to understand the intents for the larger 3D design project more accurately. The AI system is thus capable of generating 3D design objects that more accurately reflect the intents and design ideas for the larger 3D design project. In that regard, the disclosed techniques store one or more persistent intents that are associated with a larger 3D design project. Further, the disclosed techniques provide an automated process for generating composite prompts that include both inputs entered by the operator and the persistent intents. Adding the persistent intents to each of the prompts transmitted to the AI model enables the operator to clarify the overarching objectives, goals, and constraints for the larger 3D design project. Accordingly, the disclosed techniques enable the AI model to generate 3D design objects that are more responsive to the all the design intents of the operator. Accordingly, the disclosed techniques enable an operator of the CAD application to generate 3D design objects that align better with the larger 3D design project without requiring the operator to continually add the same detailed description to each prompt that the CAD application generates for the AI model. These technical advantages provide one or more technological advancements over prior art approaches.
1. In various embodiments, a computer-implemented method for generating design objects for computer-aided drawing (CAD) design, comprising combining at least two of a first input received from a first client device and one or more persistent intents to generate a composite prompt, inputting the composite prompt into a trained machine learning (ML) model for execution, receiving a design object generated by the trained ML model in response to the composite prompt, and displaying the design object in a design space that includes the CAD design.
2. The computer-implemented method of clause 1, where the one or more persistent intents includes a persona description associated with a first operator of the first client device.
3. The computer-implemented method of clause 1 or 2, where the persona description reflects a job of the first operator, a preference of the first operator, or a usage pattern of the first operator.
4. The computer-implemented method of any of clauses 1-3, further comprising executing a second trained ML model on a usage pattern of the first operator to generate the persona description.
5. The computer-implemented method of any of clauses 1-4, where the one or more persistent intents includes a design intent description that corresponds to the CAD design and is provided by a first operator of the first client device.
6. The computer-implemented method of any of clauses 1-5, where the one or more persistent intents includes an organizational intent description that corresponds to the CAD design and is received by a group of operators that includes a first operator of the first client device.
7. The computer-implemented method of any of clauses 1-6, where the organizational intent description is entered by a second operator of a second client device.
8. The computer-implemented method of any of clauses 1-7, where the first operator of the first client device is locked from modifying the organizational intent description.
9. The computer-implemented method of any of clauses 1-8, where combining at least two of a first input from a first client device and one or more persistent intents comprises applying a first weight value to the first input, and applying a set of one or more weight values to the one or more persistent intents.
10. The computer-implemented method of any of clauses 1-9, further comprising displaying, within the design space, a user interface that includes at least a portion of the one or more persistent intents.
11. In various embodiments, one or more non-transitory computer-readable media include instructions that, when executed by one or more processors, cause the one or more processors to generating design objects for computer-aided drawing (CAD) design by performing the steps of combining at least two of a first input received from a first client device and one or more persistent intents to generate a composite prompt, inputting the composite prompt into a trained machine learning (ML) model for execution, receiving a design object generated by the trained ML model in response to the composite prompt, and displaying the design object in a design space that includes the CAD design.
12. The one or more non-transitory computer-readable media of clause 11, further comprising instructions that, when executed by the one or more processors, cause the one or more processors to perform the steps of receiving feedback reflecting a responsiveness of the CAD design to the one or more persistent intents, and transmitting the feedback to the trained ML model.
13. The one or more non-transitory computer-readable media of clause 11 or 12, further comprising instructions that, when executed by the one or more processors, cause the one or more processors to perform the steps of displaying, within the design space, a user interface that includes at least a portion of the one or more persistent intents, receiving, via the user interface, feedback for at least one of the one or more persistent intents, and updating the at least one of the one or more persistent intents based on the feedback.
14. The one or more non-transitory computer-readable media of any of clauses 11-13, where the one or more persistent intents includes at least a first persistent intent and a second persistent intent, and an overall order specifies that the first persistent intent has priority the second persistent intent.
15. The one or more non-transitory computer-readable media of any of clauses 11-14, where the one or more persistent intents includes a persona description associated with a first operator of the first client device.
16. The one or more non-transitory computer-readable media of any of clauses 11-15, where the one or more persistent intents includes a design intent description that corresponds to the CAD design and is provided by a first operator of the first client device.
17. The one or more non-transitory computer-readable media of any of clauses 11-16, where the one or more persistent intents includes an organizational intent description that corresponds to the CAD design and is received by a group of operators that includes a first operator of the first client device.
18. The one or more non-transitory computer-readable media of any of clauses 11-17, where combining at least two of a first input from a first client device and one or more persistent intents comprises applying a first weight value to the first input, and applying a set of one or more weight values to the one or more persistent intents.
19. The one or more non-transitory computer-readable media of any of clauses 11-18, further comprising instructions that, when executed by the one or more processors, cause the one or more processors to perform the step of displaying, within the design space, a user interface that includes at least a portion of the one or more persistent intents.
20. In various embodiments, a system comprises one or more memories storing instructions, and one or more processors coupled to the one or more memories that, when executing the instructions, generate design objects for computer-aided drawing (CAD) design by performing the steps of combining at least two of a first input received from a first client device and one or more persistent intents to generate a composite prompt, inputting the composite prompt into a trained machine learning (ML) model for execution, receiving a design object generated by the trained ML model in response to the composite prompt, and displaying the design object in a design space that includes the CAD design.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating design objects for computer-aided drawing (CAD) design, comprising:
combining at least two of a first input received from a first client device and one or more persistent intents to generate a composite prompt;
inputting the composite prompt into a trained machine learning (ML) model for execution;
receiving a design object generated by the trained ML model in response to the composite prompt; and
displaying the design object in a design space that includes the CAD design.

2. The computer-implemented method of claim 1, wherein the one or more persistent intents includes a persona description associated with a first operator of the first client device.

3. The computer-implemented method of claim 2, wherein the persona description reflects a job of the first operator, a preference of the first operator, or a usage pattern of the first operator.

4. The computer-implemented method of claim 2, further comprising executing a second trained ML model on a usage pattern of the first operator to generate the persona description.

5. The computer-implemented method of claim 1, wherein the one or more persistent intents includes a design intent description that corresponds to the CAD design and is provided by a first operator of the first client device.

6. The computer-implemented method of claim 1, wherein the one or more persistent intents includes an organizational intent description that corresponds to the CAD design and is received by a group of operators that includes a first operator of the first client device.

7. The computer-implemented method of claim 6, wherein the organizational intent description is entered by a second operator of a second client device.

8. The computer-implemented method of claim 6, wherein the first operator of the first client device is locked from modifying the organizational intent description.

9. The computer-implemented method of claim 1, wherein combining at least two of a first input from a first client device and one or more persistent intents comprises:
applying a first weight value to the first input; and
applying a set of one or more weight values to the one or more persistent intents.

10. The computer-implemented method of claim 1, further comprising displaying, within the design space, a user interface that includes at least a portion of the one or more persistent intents.

11. One or more non-transitory computer-readable media including instructions that, when executed by one or more processors, cause the one or more processors to generating design objects for computer-aided drawing (CAD) design by performing the steps of:
combining at least two of a first input received from a first client device and one or more persistent intents to generate a composite prompt;
inputting the composite prompt into a trained machine learning (ML) model for execution;
receiving a design object generated by the trained ML model in response to the composite prompt; and
displaying the design object in a design space that includes the CAD design.

12. The one or more non-transitory computer-readable media of claim 11, further comprising instructions that, when executed by the one or more processors, cause the one or more processors to perform the steps of:
receiving feedback reflecting a responsiveness of the CAD design to the one or more persistent intents; and
transmitting the feedback to the trained ML model.

13. The one or more non-transitory computer-readable media of claim 11, further comprising instructions that, when executed by the one or more processors, cause the one or more processors to perform the steps of:
displaying, within the design space, a user interface that includes at least a portion of the one or more persistent intents;
receiving, via the user interface, feedback for at least one of the one or more persistent intents; and
updating the at least one of the one or more persistent intents based on the feedback.

14. The one or more non-transitory computer-readable media of claim 11, wherein the one or more persistent intents includes at least a first persistent intent and a second persistent intent, and an overall order specifies that the first persistent intent has priority the second persistent intent.

15. The one or more non-transitory computer-readable media of claim 11, wherein the one or more persistent intents includes a persona description associated with a first operator of the first client device.

16. The one or more non-transitory computer-readable media of claim 11, wherein the one or more persistent intents includes a design intent description that corresponds to the CAD design and is provided by a first operator of the first client device.

17. The one or more non-transitory computer-readable media of claim 11, wherein the one or more persistent intents includes an organizational intent description that corresponds to the CAD design and is received by a group of operators that includes a first operator of the first client device.

18. The one or more non-transitory computer-readable media of claim 11, wherein combining at least two of a first input from a first client device and one or more persistent intents comprises:
applying a first weight value to the first input; and
applying a set of one or more weight values to the one or more persistent intents.

19. The one or more non-transitory computer-readable media of claim 11, further comprising instructions that, when executed by the one or more processors, cause the one or more processors to perform the step of displaying, within the design space, a user interface that includes at least a portion of the one or more persistent intents.

20. A system comprising:
one or more memories storing instructions; and
one or more processors coupled to the one or more memories that, when executing the instructions, generate design objects for computer-aided drawing (CAD) design by performing the steps of:
combining at least two of a first input received from a first client device and one or more persistent intents to generate a composite prompt;
inputting the composite prompt into a trained machine learning (ML) model for execution;
receiving a design object generated by the trained ML model in response to the composite prompt; and
displaying the design object in a design space that includes the CAD design.
